(19) United States
(12) Patent Application Publication
(10) Pub. No.: US 2012/0138140 A1
(43) Pub. Date: Jun. 7, 2012

(54) ORGANIC THIN-FILM SOLAR CELL AND METHOD FOR MANUFACTURING ORGANIC THIN-FILM SOLAR CELL

(75) Inventors: Takeshi KIHARA, Tokyo-to (JP); Kouichi SUZUKI, Tokyo-to (JP)

(73) Assignee: DAI NIPPON PRINTING CO., LTD., Tokyo-to (JP)

(21) Appl. No.: 13/305,962

(22) Filed: Nov. 29, 2011

(30) Foreign Application Priority Data
Dec. 7, 2010 (JP) 2010-272652

(51) Int. Cl. H01L 31/0224; H01L 31/0296; H01L 31/0216

(52) U.S. Cl. 136/256; 438/85; 257/E31.016

(57) ABSTRACT

A main object of the invention is to provide an organic thin-film solar cell that offers high performance and is easy to form. To achieve the object, the invention provides an organic thin-film solar cell comprising: a metal electrode layer having an aluminum layer on a surface thereof, an electron extraction layer which is a zinc oxide layer formed on the aluminum layer of the metal electrode layer, a photoelectric conversion layer formed on the electron extraction layer, and a transparent electrode layer formed on the photoelectric conversion layer, wherein the electron extraction layer has a concentration gradient in which the content of oxygen atoms in the electron extraction layer tends to increase from the metal electrode layer side to the photoelectric conversion layer.

### TECHNICAL FIELD

The invention relates to an organic thin-film solar cell that offers high performance and is easy to form.

### BACKGROUND ART

An organic thin-film solar cell, which has a photoelectric conversion layer of an organic thin film placed between two different types of electrodes and having an electron donating function and an electron accepting function, is advantageous in that its manufacturing process is easier than that of an inorganic solar cell such as a silicon solar cell and it can be formed to have a large area at low cost.

An organic thin-film solar cell has a basic structure of a layered structure having a positive electrode/a photoelectric conversion layer/a negative electrode. In general, one of the electrodes is a transparent electrode, the other electrode is a metal electrode layer, and the transparent electrode, an organic layer (photoelectric conversion layer), and the metal electrode layer are laminated in this order on a transparent substrate (see for example Patent Literature 1).

To increase electric generation efficiency, an electron extraction layer is generally formed between the metal electrode layer and the photoelectric conversion layer and a hole extraction layer is formed between the photoelectric conversion layer and the transparent electrode.

One of the characteristics of an organic thin-film solar cell is that the organic layer such as the photoelectric conversion layer or the hole extraction layer can be formed by printing. To take advantage of such a characteristic, a roll-to-roll (hereinafter also referred to as R-to-R) process has been expected to be applied.

However other processes than forming these organic layers by coating, specifically, processes of forming the transparent electrode, the electron extraction layer, and the metal electrode layer and so on, are generally performed using vapor deposition processes. For example, a Ca or LiF layer generally used to form the electron extraction layer has been formed by a vapor deposition process, and there has been a problem in which the R-to-R process is difficult to employ. In addition, the Ca or LiF electron extraction layer is easily degraded under the atmosphere. Therefore, when the electron extraction layer made of such a material is used, a process with the chance of exposure to the atmosphere cannot be used, which raises the problem that the R-to-R process is difficult to employ.

In addition, for example, when the electron extraction layer is not formed, there is a problem in which the characteristics of an organic thin-film solar cell are not stable although its performance is recognized.

Citation List

Patent Literature

Patent Literature 1: Japanese Patent Application Laid-Open (JP-A) No. 2009-099805

### SUMMARY OF INVENTION

### Technical Problem

A main object of the invention, which has been made in view of the above problems, is to provide an organic thin-film solar cell that offers high performance and is easy to form.

### Solution to Problem

To solve the problems, the invention provides an organic thin-film solar cell, comprising: a metal electrode layer having an aluminum layer on a surface thereof; an electron extraction layer which is a zinc oxide layer formed on the aluminum layer of the metal electrode layer; a photoelectric conversion layer formed on the electron extraction layer; and a transparent electrode layer formed on the photoelectric conversion layer, wherein the electron extraction layer has a concentration gradient in which a content of an oxygen atoms in the electron extraction layer tends to increase from the metal electrode layer side to the photoelectric conversion layer.

According to the invention, the electron extraction layer is stable under the atmosphere, so that degradation in performance and other problems can be prevented even when any other member is formed on the electron extraction layer under the atmosphere or even when lamination or other processes are performed on the electron extraction layer under the atmosphere.

In addition, the electron extraction layer can be easily formed by performing a zincate treatment on the aluminum layer of the metal electrode layer, which can make a vapor deposition process unnecessary.

Thus, the electron extraction layer can be easily formed and have, under the atmosphere, such stability that it can be formed, for example, by a roll-to-roll process. Therefore, the product can offer high performance and be easily formed.

In the invention, the electron extraction layer preferably contains a zinc layer at a surface of the metal electrode layer side. This is because the extraction of electrons from the photoelectric conversion layer to the metal electrode layer can be easily achieved.

In the invention, the surface of the metal electrode layer, on which the electron extraction layer is formed, preferably has an arithmetic mean surface roughness Ra of 5 μm or less. This is because short-circuiting between the metal electrode layer and the transparent electrode layer can be prevented.

The invention provides a method for manufacturing an organic thin-film solar cell, in which the organic thin-film solar cell comprises a metal electrode layer having an aluminum layer on a surface thereof, an electron extraction layer which is a zinc oxide layer formed on the aluminum layer of the metal electrode layer, a photoelectric conversion layer formed on the electron extraction layer, and a transparent electrode layer formed on the photoelectric conversion layer, wherein the manufacturing method comprises a step of: treating the metal electrode layer with zincate to form the electron extraction layer on the aluminum layer of the metal electrode layer.

According to the invention, the electron extraction layer is stable under the atmosphere, so that degradation in performance and other problems can be prevented even when any other member is formed on the electron extraction layer under the atmosphere or even when lamination or other processes are performed on the electron extraction layer under the atmosphere.

Therefore, a product that offers stable performance can be easily obtained, for example, using a roll-to-roll process or the like.

### Advantageous Effects of invention

The invention is advantageously effective in providing an organic thin-film solar cell that offers high performance and is easy to form.

### BRIEF DESCRIPTION OF DRAWINGS

FIG. 1 is a schematic cross-sectional view showing an example of the organic thin-film solar cell of the invention;

FIG. 2 is a schematic cross-sectional view showing another example of the organic thin-film solar cell of the invention; and

FIGS. 3A to 3F are process drawings showing an example of the method of the invention for manufacturing an organic thin-film solar cell.

### DESCRIPTION OF EMBODIMENTS

The invention relates to an organic thin-film solar cell and a method for manufacture thereof.

Hereinafter, the organic thin-film solar cell of the invention and the method of the invention for manufacturing an organic thin-film solar cell are described in detail.

A. Organic Thin-Film Solar Cell

First, a description is given of the organic thin-film solar cell of the invention.

The organic thin-film solar cell of the invention comprises: a metal electrode layer having an aluminum layer on a surface thereof; an electron extraction layer which is a zinc oxide layer formed on the aluminum layer of the metal electrode layer; a photoelectric conversion layer formed on the electron extraction layer; and a transparent electrode layer formed on the photoelectric conversion layer, wherein the electron extraction layer has a concentration gradient in which the content of an oxygen atom in the electron extraction layer tends to increase from the metal electrode layer side to the photoelectric conversion layer.

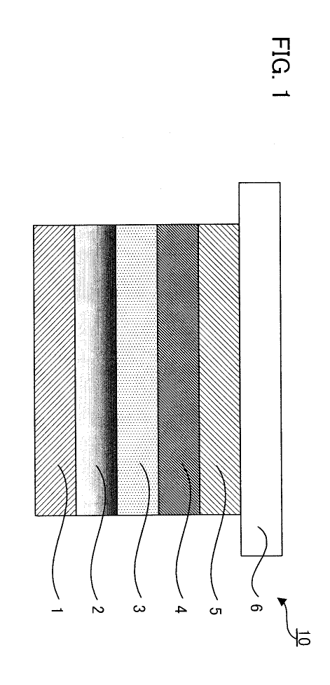

Such an organic thin-film solar cell according to the invention is described with reference to the drawings. FIG. 1 is a schematic cross-sectional view illustrating an example of the organic thin-film solar cell of the invention. As illustrated in FIG. 1, the organic thin-film solar cell 10 comprises: a metal electrode layer 1 made of an aluminum foil, an electron extraction layer 2 which is a zinc oxide layer formed on the metal electrode layer 1 and having a concentration gradient in which the oxygen atom content tends to increase from the metal electrode layer side to a photoelectric conversion layer, a photoelectric conversion layer 3 formed on the electron extraction layer 2, a hole extraction layer 4 formed on the photoelectric conversion layer 3, a transparent electrode layer 5 formed on the hole extraction layer 4, and a transparent substrate 6 formed on the transparent electrode layer 5.

According to the invention, the material of the electron extraction layer is stable under the atmosphere as compared with materials conventionally used to form electron extraction layers, such as Ca and LiF, which are easily converted into insulating materials under the atmosphere. Therefore, after the electron extraction layer is formed, degradation in performance and other problems can be prevented even when any other member is formed on the electron extraction layer under the atmosphere or even when lamination or other processes are performed on the electron extraction layer under the atmosphere.

The electron extraction layer can be easily formed by performing a zincate treatment on the aluminum layer of the metal electrode layer, which can make a vapor deposition process required when a conventional material such as Ca or LiF is used as a material for an electron extraction layer unnecessary.

Thus, the electron extraction layer can be easily formed, and for example, the organic thin-film solar cell can be formed with a roll-to-roll process, by preparing a negative electrode side substrate which includes the metal electrode layer and the electron extraction layer and a positive electrode side substrate which includes the transparent substrate and the transparent electrode layer, to laminate the substrates.

Therefore, the product having the electron extraction layer can offer high performance and be easily formed.

When formed by a zincate treatment, the electron extraction layer can be easily reduced in thickness, so that a highly-flexible, negative-electrode-side substrate and so on can be formed. Therefore, for example, the negative electrode side substrate can be used in the form of a roll, which makes it easy to employ a roll-to-roll process.

The organic thin-film solar cell of the invention comprises at least a metal electrode layer, an electron extraction layer, a photoelectric conversion layer, and a transparent electrode layer.

Hereinafter, each component of the organic thin-film solar cell of the invention is described in detail.

1. Metal Electrode Layer

The metal electrode layer for use in the invention has an aluminum layer on a surface thereof.

Such a metal electrode layer may be of any type as long as it has an aluminum layer on the surface thereof, namely, it has a surface in which aluminum is exposed, and can function as an electrode. Specifically, the metal electrode layer may be made of aluminum, namely, consist of an aluminum layer, or may include a supporting substrate or the like which has a surface coated with an aluminum layer.

In the invention, it is particularly preferred that the metal electrode layer is made of aluminum, specifically, an aluminum foil. This is because such a layer has a high ability to receive electrons from the electron extraction layer. This is also because the use of such a layer makes it possible to easily form the zinc oxide layer of the electron extraction layer by a zincate treatment. In addition, when an aluminum foil is used, an R-to-R process is advantageously performed by, such as, unwinding the aluminum foil in roll and forming the electron extraction layer thereon.

As used herein, the term “aluminum foil” refers to a material made of aluminum and having flexibility. The term “having flexibility” means that the material bends when a force of 5 kN is applied thereto in the metal material bending test method according to JIS Z 2248.

In the invention, any material having a surface on which an aluminum layer can be formed, such as a glass material, a metal material, or a resin, may be used to form the supporting substrate.

In the invention, a material having flexibility, such as a metal foil made of a metal material or a film made of resin is particularly preferred. This is because an R-to-R process can be advantageously performed as described above.

Examples of the metal material that may be used in the invention include gold (Au), silver (Ag), cobalt (Co), nickel (Ni), platinum (Pt), copper (Cu), titanium (Ti), iron (Fe), a stainless metal, an aluminum alloy, a copper alloy, a titanium alloy, an iron-nickel alloy, and a nickel-chromium (Ni—Cr) alloy.

Specifically, the resin may be a cellulose-based resin such as ethyl cellulose, methyl cellulose, nitrocellulose, acetyl cellulose, acetyl ethyl cellulose, cellulose propionate, hydroxypropyl cellulose, butyl cellulose, benzyl cellulose, or nitrocellulose; an acrylic-based resin including a polymer or copolymer of methyl methacrylate, ethyl methacrylate, tertiary-butyl methacrylate, normal-butyl methacrylate, isobutyl methacrylate, isopropyl methacrylate, 2-ethyl methacrylate, 2-ethylhexyl methacrylate, or 2-hydroxyethyl methacrylate; or a polyhydric alcohol such as polyethylene glycol.

When the metal electrode layer is a supporting substrate having a surface coated with an aluminum layer, any part of the surface of the supporting substrate may be coated with the aluminum layer, as long as it includes a surface side on which at least the electron extraction layer is formed. In particular, however, it preferably includes the whole of the surface on which the electron extraction layer is formed. This is because by the presence of the aluminum layer, the zinc oxide layer of the electron extraction layer can be easily formed by a zincate treatment. This is also because the ability to receive electrons from the electron extraction layer can be made high.

The aluminum layer formed on the supporting substrate may have any thickness, as long as it can be stably formed on the supporting substrate. For example, the thickness may be in the range of 1 μm to 1 mm.

The metal electrode layer for use in the invention may have any thickness as long as it functions as an electrode. Specifically, the thickness may be 10 μm or more, and from about 10 μm to about 3 mm. On the other hand, the smaller the thickness is, the more the flexibility is achieved. Taking flexibility into account, the thickness is preferably in the range of 10 μm to 300 μm, and more preferably in the range of 30 μm to 300 μm.

The arithmetic mean surface roughness Ra of the surface of the metal electrode layer for use in the invention, on which the electron extraction layer is formed, is not limited as long as the resulting cell can be used stably. However, the arithmetic mean surface roughness Ra is preferably 5 μm or less, more preferably 1 μm or less, and in particular, preferably 0.5 μm or less. This is because if the surface roughness is in the above range, short-circuiting between the metal electrode layer and the transparent electrode layer can be prevented more stably. The arithmetic mean surface roughness Ra generally has a lowest limit of 0.001 μm or more, which is in the actually controllable range.

The arithmetic mean surface roughness Ra can be determined by the method defined in JIS B 0601-1994.

2. Electron Extraction Layer

The electron extraction layer for use in the invention is a zinc oxide layer formed on the aluminum layer of the metal electrode layer and has a concentration gradient in which the content of oxygen atoms in the electron extraction layer tends to increase from the metal electrode layer side to the photoelectric conversion layer.

The inventive feature that the electron extraction layer contains zinc oxide and has the concentration distribution stated above can be determined by a process that includes performing elemental analysis in the depth direction by X-ray photoelectron spectroscopy (XPS) to detect the degree of oxidation of Zn in the depth direction so that the gradient structure of the material can be detected in the depth direction.

The content of oxygen atoms in the electron extraction layer is not restricted as long as it shows a tendency to increase from the metal electrode layer side to the photoelectric conversion layer. In a preferred mode, the content of oxygen atoms in the electron extraction layer should be substantially 0 at the surface of the metal electrode layer side, namely, the electron extraction layer should have a zinc metal (Zn) layer at the surface of the metal electrode layer side. This is because the extraction of electrons from the photoelectric conversion layer to the metal electrode layer can be easily achieved. This is also because the adhesion strength between the metal electrode layer and the electron extraction layer can be improved so that an electrode structure with high connection reliability can be achieved.

The feature that the content is substantially 0 so that a zinc metal (Zn) layer is provided means that the electron extraction layer is formed by a process including depositing zinc on the aluminum layer of the metal electrode layer by a zincate treatment or the like to form a zinc layer and then oxidizing the surface of the zinc layer. Specifically, it means that the content of zinc in the zinc or zinc oxide part of the surface of the metal electrode layer side of the electron extraction layer is 95% or more, preferably 98% or more, and in particular, preferably 100%. Therefore, the electron extraction layer (zinc oxide layer) preferably has a zinc layer made of zinc at the surface of the metal electrode layer side. This is because higher connection reliability and so on can be achieved.

The electron extraction layer for use in the invention, which contains oxygen and zinc atoms, may contain other components as long as they do not inhibit the extraction of electrons from the photoelectric conversion layer to the metal electrode layer.

In the invention, while the thickness of the electron extraction layer is not limited as long as the desired function of extracting electrons can be produced, it is preferably in the range of 0.1 μm to 5 μm, more preferably in the range of 0.1 μm to 1 μm, and in particular, preferably in the range of 0.1 μm to 0.5 μm. This is because when the thickness is in the above range, the electron extraction layer can be formed with a reduced number of pinholes and so on.

The electron extraction layer for use in the invention may be formed at any location (in planar view) where there is a region in which the metal electrode layer and the photoelectric conversion layer overlap each other in planar view. Preferably, it should be formed at the whole of the region where the metal electrode layer and the photoelectric conversion layer overlap each other in planar view. This is because high photoelectric conversion efficiency can be obtained.

The electron extraction layer may also be formed on any surface of the metal electrode layer as long as the surface includes at least the surface of the photoelectric conversion layer side of the metal electrode layer. While it maybe formed on both surfaces of the metal electrode layer, it is preferably formed only on the photoelectric conversion layer side surface of the metal electrode layer. This is because if the zinc oxide layer is formed on the back surface, electric resistance may be high at the contact point in the connection to an external electric circuit through the back electrode, so that the connection reliability may be reduced.

While the electron extraction layer for use in the invention may be formed by any method capable of forming the zinc oxide layer with high precision, it is preferably formed using a method of performing a zincate treatment on the surface of the aluminum layer of the metal electrode layer. Such a method makes it possible to easily form the electron extraction layer and to form a thin layer.

The zincate treatment of the aluminum layer surface may be performed using a general method, specifically using a method that includes immersing the aluminum layer of the metal electrode layer in a zincate bath containing an alkaline solution including zincate ions and then performing drying under the atmosphere. In such a method, a zinc layer is successfully formed on the aluminum layer in the zincate bath, and the drying under the atmosphere enables oxidation of the surface of the zinc layer so that the electron extraction layer can be formed of a zinc oxide layer having a concentration gradient in which the oxygen atom content tends to increase from the metal electrode layer side to the photoelectric conversion layer.

A common zincate bath may be used, and specifically, a zincate bath containing a zinc compound such as ZnO and an alkali hydroxide such as NaOH or KOH and having a pH of 13 or more may be used. While the temperature of the zincate bath should be appropriately set depending on the thickness or other properties of the electron extraction layer to be formed, the temperature condition may be from 10° C. to 60° C. The immersion time should be appropriately set depending on the thickness or other properties.

A method of forming the electron extraction layer in a certain pattern by a zincate treatment may include a method of placing a resist over the area other than the region where the electron extraction layer will be formed.

3. Photoelectric Conversion Layer

The photoelectric conversion layer for use in the invention may be a single layer having both an electron accepting function and an electron donating function (a first mode) or a laminate of an electron accepting layer having an electron accepting function and an electron donating layer having an electron donating function (a second mode). Hereinafter, each mode is described.

(1) First Mode

In the invention, a first mode of the photoelectric conversion layer is a single layer having both an electron accepting function and an electron donating function, which contains an electron donating material and an electron accepting material. In this photoelectric conversion layer, charge separation is generated based on the p-n junction formed therein, so that it functions by itself.

While such an electron donating material may be any material having an electron donating function, it is preferably capable of being formed into a film by a wet coating method, and in particular, it is preferably an electron-donating, conductive, polymer material.

The conductive polymer is a so-called π-conjugated polymer, which includes a π-conjugated system, in which a carbon-carbon or heteroatom-containing double or triple bond and a single bond are linked alternately, and exhibits semiconducting properties. The conductive polymer material has developed π-conjugation in the main polymer chain and therefore is basically advantageous in transporting charges in the main chain direction. In addition, the electron transfer mechanism of the conductive polymer is mainly hopping conduction between π-stacked molecules, and therefore, the conductive polymer material is advantageous in transporting charges not only in the main polymer chain direction but also in the thickness direction of the photoelectric conversion layer. When a coating liquid including a solution or dispersion of the conductive polymer material in a solvent is used, a film of the conductive polymer material can be easily formed by a wet coating method. Therefore, the conductive polymer material is advantageous in that a large-area organic thin-film solar cell can be produced at low cost without necessity for expensive equipment.

Examples of the electron-donating conductive polymer material include polyphenylene, polyphenylene vinylene, polysilane, polythiophene, polycarbazole, polyvinylcarbazole, porphyrin, polyacetylene, polypyrrole, polyaniline, polyfluorene, polyvinylpyrene, polyvinylanthracene, derivatives thereof, and copolymers thereof, or phthalocyanine-containing polymers, carbazole-containing polymers, and organometallic polymers.

Among the above, preferably used are thiophene-fluorene copolymers, polyalkylthiophene, phenylene ethynylene-phenylene vinylene copolymers, phenylene ethynylene-thiophene copolymers, phenylene ethynylene-fluorene copolymers, fluorene-phenylene vinylene copolymers, and thiophene-phenylene vinylene copolymers. These are appropriately different in energy level from many electron accepting materials.

For example, a detailed method for synthesis of a phenylene ethynylene-phenylene vinylene copolymer (poly [1, 4-phenyleneethynylene-1, 4-(2, 5-dioctadodecyloxyphenylene)-1, 4-phenyleneethene-1, 2-diyl-1, 4-(2, 5-dioctadodecyloxyphenylene)ethene-1,2-diyl]) is described in Macromolecules, 35, 3825 (2002) or Mcromol. Chem. Phys., 202, 2712 (2001).

Examples of polyalkylthiophene include P3HT (poly (3-hexylthiophene-2, 5-diyl)) and so on.

While the electron accepting material may be any materials having an electron accepting function, it is preferably capable of being formed into a film by a wet coating method, and in particular, it is preferably an electron-accepting conductive polymer material. The conductive polymer material has advantages as described above.

Examples of the electron-accepting conductive polymer material for use in this mode include polyphenylene vinylene, polyfluorene, derivatives thereof, and copolymers thereof, or carbon nanotubes, fullerene derivatives, CN or CF₃ group-containing polymers, and —CF₃-substituted polymers thereof. Examples of polyphenylene vinylene derivatives include CN-PPV
(poly[2-methoxy-5-(2′-ethylhexyloxy)-1, 4-(1-cyanovinylene)phenylene]) and MEH-CN-PPV
(poly[2-methoxy-5-(2′ -ethylhexyloxy)-1, 4-(1-cyanovinylene)phenylene]).

Examples of fullerene derivatives include PCBM (phenyl C61 butyric acid methyl ester) and so on.

An electron accepting material doped with an electron donating compound or an electron donating material doped with an electron accepting compound may also be used. In particular, a conductive polymer material doped with such an electron donating compound or an electron accepting compound is preferably used. This is because the conductive polymer material has developed π-conjugation in the main polymer chain and therefore is basically advantageous in transporting charges in the main chain direction and because charges are produced in the π-conjugated main chain by the doping with an electron donating compound or an electron accepting compound so that the electric conductivity can be significantly increased.

As an example of the electron-accepting conductive polymer material doped with the electron donating compound of the present mode, the above-mentioned electron-accepting conductive polymer material may be cited. Examples of the electron donating compound that may be used as a dopant include Lewis bases such as alkali metals and alkaline earth metals, such as Li, K, Ca, and Cs. Lewis bases act as electron donors.

As an example of the electron-donating conductive polymer material doped with the electron accepting compound, the above-mentioned electron donating conductive polymer material may be cited. Examples of the electron accepting compound that may be used as a dopant include Lewis acids such as FeCl₃ (III), AlCl₃, AlBr₃, AsF₆, and halogen compounds. Lewis acids act as electron acceptors.

In this mode, the thickness of the photoelectric conversion layer used may be a thickness used in a common bulk hetero-junction organic thin-film solar cell. Specifically, the thickness may be set in the range of 0.2 nm to 3,000 nm, and preferably in the range of 1 nm to 600 nm. If the thickness is more than the above range, the volume resistance of the photoelectric conversion layer may increase. If the thickness is less than the above range, the layer may fail to sufficiently absorb light.

In this mode, the mixing ratio between the electron donating material and the electron accepting material is appropriately controlled to be optimal depending on the type of the materials used.

In this mode, while the photoelectric conversion layer maybe formed by any method capable of uniformly forming a film with a predetermined thickness, it is preferably formed using a wet coating method. When a wet coating method is used, the photoelectric conversion layer can be formed in the atmosphere, so that the cost can be reduced and that a large-area product can be easily formed.

In this mode, a coating liquid for forming the photoelectric conversion layer may be applied by any method capable of uniformly applying the coating liquid, such as a die coating, a spin coating, a dip coating, a roll coating, a bead coating, a spray coating, a bar coating, a gravure coating, an inkjet process, a screen printing, or an offset printing.

In particular, the photoelectric conversion layer coating liquid is preferably applied by a method capable of controlling the thickness mainly based on the amount of coating. Examples of such a method capable of controlling the thickness mainly based on the amount of coating include a die coating, a bead coating, a bar coating, a gravure coating, an inkjet process, and printing methods such as a screen printing and an offset printing. Printing methods are advantageous in forming a large-area organic thin-film solar cell.

After the photoelectric conversion layer coating liquid is applied, the coating film formed may be subjected to a drying process. In this case, the solvent and so on can be quickly removed from the photoelectric conversion layer coating liquid so that productivity can be improved.

The drying process may be performed using a common method such as drying by heating, drying by blowing, vacuum drying, or drying by infrared heating.

(2) Second Mode

In the invention, a second mode of the photoelectric conversion layer is a laminate of an electron accepting layer having an electron accepting function and an electron donating layer having an electron donating function. Hereinafter, the electron accepting layer and the electron donating layer are described.

(Electron Accepting Layer)

The electron accepting layer used in this mode has an electron accepting function and contains an electron accepting material.

While such an electron accepting material may be of any type capable of functioning as an electron acceptor, it is preferably capable of being formed into a film by a wet coating method, and in particular, it is preferably an electron-accepting conductive polymer material. Such a conductive polymer material has the advantages described above. Specifically, the conductive polymer material may be the same as the electron-accepting conductive polymer material used in the first mode of the photoelectric conversion layer.

In this mode, the thickness of the electron accepting layer may be a thickness used in a common bilayer organic thin-film solar cell. Specifically, the thickness may be set in the range of 0.1 nm to 1500 nm, and preferably in the range of 1 nm to 300 nm. If the thickness is more than the above range, the volume resistance of the electron accepting layer may increase. If the thickness is less than the above range, the layer may fail to sufficiently absorb light.

In this mode, the electron accepting layer may be formed by the same method as the method of forming the first mode of the photoelectric conversion layer.

(Electron Donating Layer)

The electron donating layer used in this mode has an electron donating function and contains an electron donating material.

While such an electron donating material of the present mode may be of any type capable of functioning as an electron donor, it is preferably capable of being formed into a film by a wet coating method, and in particular, it is preferably an electron-donating conductive polymer material. Such a conductive polymer material has the advantages described above. Specifically, the conductive polymer material may be the same as the electron-donating conductive polymer material used in the first mode of the photoelectric conversion layer.

In this mode, the thickness of the electron donating layer may be a thickness used in a common bilayer organic thin-film solar cell. Specifically, the thickness maybe set in the range of 0.1 nm to 1500 nm, and preferably in the range of 1 nm to 300 nm. If the thickness is more than the above range, the volume resistance of the electron donating layer may increase. If the thickness is less than the above range, the layer may fail to sufficiently absorb light.

In this mode, the electron donating layer may be formed by the same method as the method of forming the first mode of the photoelectric conversion layer.

4. Transparent Electrode Layer

In the invention, the transparent electrode layer is formed on a transparent substrate and is a counter electrode to the metal electrode layer. The transparent electrode layer is generally used as an electrode (a hole extraction electrode) to extract holes generated in the photoelectric conversion layer. In the invention, the transparent electrode layer side forms a light receiving surface.

In the invention, the transparent electrode layer may be of any type capable of serving as a light receiving side electrode and may be a transparent electrode or a laminate of a transparent electrode and a patterned auxiliary electrode.

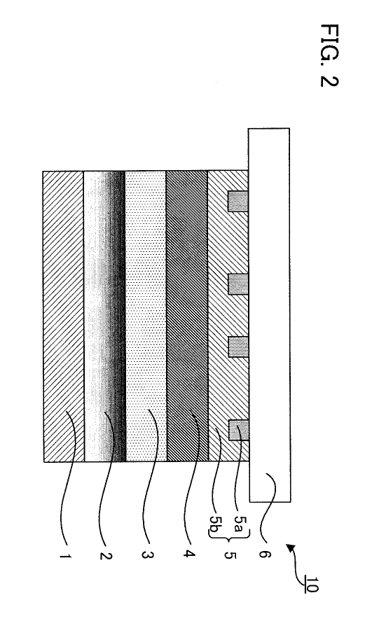

As illustrated in FIG. 2, when the transparent electrode layer 5 is a laminate of a patterned auxiliary electrode 5a and a transparent electrode 5b, the sheet resistance of the auxiliary electrode can be sufficiently reduced so that the total resistance of the transparent electrode layer can be reduced, even though the transparent electrode has a relatively high sheet resistance. Therefore, the generated power can be efficiently collected.

Hereinafter, the transparent electrode and the auxiliary electrode are described.

(1) Transparent Electrode

The transparent electrode for use in the invention is formed on a transparent substrate.

Such a transparent electrode may be made of any material having conductivity and transparency and examples may be In—Zn—O (IZO), In—Sn—O (ITO), ZnO—Al, Zn—Sn—O, high-conductivity PEDOT/PSS (e.g., Orgacon-S303™ manufactured by Agfa-Gevaert Group) , ITO nano-ink, or ZnO nano-ink.

In the invention, it is particularly preferred that such a material should be appropriately selected taking into account the work function and other characteristics of the material used to form the metal electrode layer. For example, when the metal electrode layer is made of a material with a low work function, the transparent electrode is preferably made of a material with a high work function.

In the invention, the material used to form the transparent electrode is preferably capable of being subjected to a coating method, so that the transparent electrode can be easily formed.

Specific examples of such a material that is preferably used include the high-conductivity PEDOT/PSS (e.g., Orgacon-S303™ manufactured by Agfa-Gevaert Group), ITO nano-ink, and ZnO nano-ink. In particular, the high-conductivity PEDOT/PSS (e.g., Orgacon-S303™ manufactured by Agfa-Gevaert Group) is preferably used. Such a material can be easily used in the form of a coating liquid so that the transparent electrode according to the invention can be easily formed by a wet process such as a coating method. This makes it possible to avoid a vapor deposition process, which would otherwise be necessary to form a common ITO electrode or the like.

When formed using the ITO nano-ink or ZnO nano-ink, the transparent electrode tends to have high resistance, and therefore, it is preferably used in combination with the auxiliary electrode described below.

In the invention, the transparent electrode preferably has a total light transmittance of 85% or more, more preferably 90% or more, and in particular, preferably 92% or more. When the total light transmittance of the transparent electrode is in the above range, light can sufficiently pass through the transparent electrode, so that the photoelectric conversion layer can efficiently absorb light.

The total light transmittance is the value measured in the visible light region using SM Color Computer (model SM-C™) manufactured by Suga Test Instruments Co., Ltd.

In the invention, the transparent electrode preferably has a sheet resistance of 20Ω/square or less, more preferably 10Ω/square or less, and in particular, preferably 5Ω/square or less. If the sheet resistance is more than the above range, the generated charges may fail to be sufficiently transferred to the external circuit.

The sheet resistance is the value measured according to JIS R 1637 (Test Method for Resistivity of Fine Ceramic Thin Films with a Four-Point Probe Method) using a surface resistance meter manufactured by Mitsubishi Chemical Corporation (Loresta MCP™, four terminal probe).

In the invention, the transparent electrode may be a single layer or a laminate of materials with different work functions.

The thickness of the transparent electrode, which corresponds to the thickness of a single layer or the total thickness of two or more layers, is preferably in the range of 0.1 nm to 500 nm, and in particular, preferably in the range of 1 nm to 300 nm. If the thickness is less than the above range, the transparent electrode may have too high sheet resistance, so that the generated charges may fail to be sufficiently transferred to the external circuit. If the thickness is more than the above range, the total light transmittance may be reduced, so that the photoelectric conversion efficiency may be reduced.

In the invention, the transparent electrode may be formed using a general electrode-forming method. Specifically, a vapor deposition process, a process of applying a transparent electrode coating liquid containing any of the above materials, or any other process may be used.

The same coating methods as those described in the section “3. Photoelectric Conversion Layer” may be used.

(2) Auxiliary Electrode

The auxiliary electrode for use in the invention is formed in a certain pattern on the transparent substrate. The auxiliary electrode generally has a resistance value lower than that of the transparent electrode.

The material used to form the auxiliary electrode is generally metal. Examples of the metal used to form the auxiliary electrode include electrically-conductive metals such as aluminum (Al), gold (Au), silver (Ag), cobalt (Co), nickel (Ni), platinum (Pt), copper (Cu), titanium (Ti), iron (Fe), stainless steel metals, aluminum alloys, copper alloys, titanium alloys, iron-nickel alloys, and nickel-chromium (Ni—Cr) alloys. Among these electrically-conductive metals, metals with relatively low electrical resistance are preferred. Such electrically-conductive metals include Al, Au, Ag, and Cu.

The auxiliary electrode may be a single layer made of an electrically-conductive metal as described above or a laminate of an electrically-conductive metal layer and a contact layer, which are appropriately laminated to improve adhesion to the transparent substrate or the transparent electrode. Examples of the material used to form the contact layer include nickel (Ni), chromium (Cr), nickel-chromium (Ni—Cr), titanium (Ti), and tantalum (Ta). The contact layer is laminated on the electrically-conductive metal layer so that the desired adhesion between the auxiliary electrode and the substrate or the transparent electrode can be obtained, and the contact layer or layers may be placed on only one or both sides of the electrically-conductive metal layer.

A preferred metal may be selected depending on factors such as the work function of the metal electrode layer-forming material. For example, when the work function of the metal electrode layer-forming material is taken into account, it is preferred that the metal used to form the auxiliary electrode should have a high work function, because the transparent electrode layer serves as a hole extraction electrode. Specifically, Al is preferably used.

In the invention, the auxiliary electrode may be of any shape as long as it has a certain pattern, and the shape of the auxiliary electrode is appropriately selected depending on factors such as the desired conductivity, transparency, or strength. For example, the auxiliary electrode may have a mesh part, which is in the form of a mesh, and a frame part placed around the mesh part, or may consist of a mesh part, which is in the form of a mesh.

When the auxiliary electrode has a mesh part and a frame part, the mesh and frame parts may be arranged in such a manner that, for example, when the auxiliary electrode is rectangular, the frame part surrounds the four sides of the mesh part, three sides of the mesh part, or two sides of the mesh part, or placed along one side of the mesh part. In particular, the frame part is preferably placed to surround four or three sides of the mesh part, so that electric power can be efficiently collected.

In the invention, the mesh part may have any shape as long as it is in the form of a mesh, and the shape maybe appropriately selected depending on factors such as the desired conductivity, transparency, or strength. For example, it may be a polygonal lattice structure such as a triangular, quadrangular, or hexagonal lattice structure, a circular lattice structure, or any other lattice structure. The polygonal or circular “lattice structure” means a structure in which polygons or circles are periodically arranged. In the polygonal or circular lattice structure, for example, polygonal openings may be straightly arranged or arranged in zigzag.

In particular, the mesh part preferably has a hexagonal lattice structure or a parallelogram lattice structure. This is because the current flowing through the mesh part can be prevented from being localized. Particularly in the case of a hexagonal lattice structure, hexagonal openings are preferably zigzag arranged (in a so-called honeycomb pattern). In the case of a parallelogram lattice structure, the parallelogram preferably has an acute angle in the range of 40° to 80°, more preferably in the range of 50° to 70°, and even more preferably in the range of 55° to 65°.

Since the auxiliary electrode itself basically does not transmit light, the light enters the photoelectric conversion layer from the openings of the mesh part of the auxiliary electrode. Therefore, the mesh part of the auxiliary electrode preferably has relatively large openings. Specifically, the mesh part of the auxiliary electrode preferably has an opening ratio in the range of about 50% to about 98%, more preferably in the range of 70% to 98%, and even more preferably in the range of 80% to 98%.

In the auxiliary electrode, the pitch of the openings of the mesh part and the line width of the mesh part may be appropriately selected depending on the area of the whole of the auxiliary electrode or other features.

The line width of the frame part may also be appropriately selected depending on the area of the whole of the auxiliary electrode or other features.

The thickness of the auxiliary electrode is not limited, as long as it is such that no short circuit occurs between the transparent electrode layer and the metal electrode layer, and it may be appropriately selected depending on the thickness of the photoelectric conversion layer, the hole extraction layer, the electron extraction layer, or the like. Specifically, when the total thickness of the layers formed between the transparent electrode layer and the metal electrode layer (such as the photoelectric conversion layer, the hole extraction layer, and the electron extraction layer) is normalized as 1, the thickness of the auxiliary electrode is preferably 5 or less, more preferably 3 or less, even more preferably 2 or less, in particular, preferably 1.5 or less, and the most preferably 1 or less. If the thickness of the auxiliary electrode exceeds the above range, a short circuit may occur between the electrodes. More specifically, the thickness of the auxiliary electrode is preferably in the range of 100 nm to 1000 nm, more preferably in the range of 200 nm to 800 nm, even more preferably in the range of 200 nm to 500 nm, and in particular, preferably in the range of 200 nm to 400 nm. If the thickness of the auxiliary electrode is less than the above range, the sheet resistance of the auxiliary electrode may become too high. If the thickness of the auxiliary electrode is more than the above range, a short circuit may occur between the electrodes.

Particularly when the photoelectric conversion layer is formed on the transparent electrode layer by a method capable of controlling the thickness mainly based on the amount of coating, the thickness of the auxiliary electrode is preferably in the range of 200 nm to 300 nm. When the photoelectric conversion layer is formed on the transparent electrode layer by the method capable of controlling the thickness mainly based on the amount of coating, setting the thickness of the auxiliary electrode at more than the above range can make it difficult to cover the edge of the mesh or frame part of the auxiliary electrode, so that a short circuit may be more likely to occur between the electrodes. Also if the thickness of the auxiliary electrode is more than the above range, the photoelectric conversion layer may be formed with a thickness greater than the desired thickness due to the surface tension. If the photoelectric conversion layer is too thick, it may exceed the electron diffusion length and the hole diffusion length, so that the conversion efficiency may be reduced. The thickness of the auxiliary electrode is preferably controlled so that the photoelectric conversion layer is prevented from being formed with a thickness greater than the desired thickness due to the surface tension. Particularly, the distance which holes and electrons can travel in a photoelectric conversion layer is known to be about 100 nm, and also from this point, the thickness of the auxiliary electrode is preferably controlled so that the photoelectric conversion layer is prevented from being formed with a thickness greater than the desired thickness due to the surface tension.

On the other hand, for example, when the photoelectric conversion layer is formed by spin coating, the centrifugal force can make the film uniform, so that the edge of the auxiliary electrode can be covered even when the auxiliary electrode is relatively thick. In the case of spin coating, the thickness can also be controlled by the number of revolutions, which makes it possible to obtain a uniform film even when the auxiliary electrode is relatively thick.

Thus, when the photoelectric conversion layer is formed by the method capable of controlling the thickness mainly based on the amount of coating, the above range is particularly preferred.

In the invention, the auxiliary electrode may have any sheet resistance lower than the sheet resistance of the transparent electrode. Specifically, the auxiliary electrode preferably has a sheet resistance of 5Ω/square or less, more preferably 3Ω/square or less, even more preferably 1Ω/square or less, in particular, preferably 0.5Ω/square or less, and the most preferably 0.1Ω/square or less. If the sheet resistance of the auxiliary electrode is more than the above range, the desired power generation efficiency cannot be obtained in some cases.

The sheet resistance is the value measured according to JIS R 1637 (Test Method for Resistivity of Fine Ceramic Thin Films with a Four-Point Probe Method) using a surface resistance meter manufactured by Mitsubishi Chemical Corporation (Loresta MCP™, four terminal probe).

Concerning the order of laminating the transparent electrode and the auxiliary electrode in the invention, the auxiliary electrode and the transparent electrode may be laminated in this order on the transparent substrate, or the transparent electrode and the auxiliary electrode may be laminated in this order on the transparent substrate. In particular, the auxiliary electrode and the transparent electrode are preferably laminated in this order on the transparent substrate. This is because a larger contact area between the transparent electrode and the photoelectric conversion layer or the hole extraction layer or the like can provide better adhesion at the interface and achieve higher hole transfer efficiency.

In the invention, the method of forming the auxiliary electrode is typically, but not limited to, a method that includes steps of forming a metal thin film on the entire surface and then patterning the metal thin film into a mesh structure, or a method of directly forming a mesh conductor. These methods are appropriately selected depending on factors such as the auxiliary electrode-forming material or structure.

In the invention, the metal thin film is preferably formed by a vacuum film forming method such as vacuum deposition, sputtering, or ion plating. Therefore, the auxiliary electrode is preferably a metal thin film formed by a vacuum film forming method. Metal species formed by a vacuum film forming method can have less inclusion content and a lower specific resistance than plating films. Metal thin films formed by a vacuum film forming method can also have a lower specific resistance than films produced with a Ag paste or the like. The vacuum film forming method is also advantageous in forming a metal thin film with a uniform thickness of 1 μm or less, preferably 50 nm or less, under precise control of the thickness.

The metal thin film may be patterned not limited to but by any method capable of forming the desired pattern with high precision, and an example of which is photo-etching.

5. Organic Thin-Film Solar Cell

The organic thin-film solar cell of the invention, comprises at least the metal electrode layer, the electron extraction layer, the photoelectric conversion layer, and the transparent electrode layer, may generally comprises a transparent substrate on which the transparent electrode layer is formed, and a hole extraction layer formed between the transparent electrode layer and the photoelectric conversion layer.

If necessary, the organic thin-film solar cell of the invention may have any of the components mentioned below. For example, the organic thin-film solar cell of the invention may have a protective sheet or a functional layer such as a filler layer, a barrier layer, a protective hard-coat layer, a strength supporting layer, an anti-fouling layer, a high light-refection layer, a light confining layer, or a sealer layer. A bonding layer may also be formed between the respective functional layers depending on the layered structure.

These functional layers may be those disclosed in a publication such as Japanese Patent Application Laid-Open No. 2007-0073717 Publication.

(1) Transparent Substrate

The transparent substrate for use in the invention may be of any type, such as a non-flexible transparent rigid member such as a quartz glass, PYREX (registered trademark), or a synthetic quartz plate; or a flexible transparent member such as a transparent resin film or an optical resin plate.

In particular, the transparent substrate is preferably a flexible member such as a transparent resin film. The transparent resin film has good workability, is useful for reducing the manufacturing cost or the weight, for example, by use of an R-to-R process, and for forming a crack-resistant organic thin-film solar cell, and therefore can be used in a wide variety of applications including curved surface applications.

(2) Hole Extraction Layer

In the invention, as already illustrated in FIG. 1, a hole extraction layer 4 may be formed between the photoelectric conversion layer 3 and the transparent electrode layer 5. The hole extraction layer is provided to facilitate the extraction of holes from the photoelectric conversion layer to the hole extraction electrode (transparent electrode layer). This increases the efficiency of the extraction of holes from the photoelectric conversion layer to the hole extraction electrode, so that the photoelectric conversion efficiency can be improved.

In the invention, the material used to form the hole extraction layer may be any material capable of stabilizing the extraction of holes from the photoelectric conversion layer to the hole extraction electrode. Examples include electrically-conductive organic compounds such as doped polyaniline, polyphenylene vinylene, polythiophene, polypyrrole, polyparaphenylene, polyacetylene, and triphenyldiamine (TPD); and organic materials that form a charge transfer complex composed of an electron donating compound such as tetrathiofulvalene or tetramethylphenylenediamine and an electron accepting compound such as tetracyanoquinodimethane or tetracyanoethylene. A thin film of a metal or the like such as Au, In, Ag, or Pd may also be used. The thin film of a metal or the like may be used alone or in combination with the organic material.

In particular, water-dispersible polyethylenedioxythiophene (PEDOT), polyethylenedioxythiophene-polystyrene sulfonic acid (PEDOT-PSS), polyaniline, or polypyrrole is preferably used.

In the invention, when the organic thin-film solar cell is produced by laminating a negative electrode side substrate and a positive electrode side substrate as described above, polyethylenedioxythiophene-polystyrene sulfonic acid (PEDOT-PSS) is preferably used to form the hole extraction layer. This is because the PEDOT-PSS can exhibit high adhesion to the photoelectric conversion layer, when it is used at the interface in the lamination, specifically, in the process of laminating a negative electrode side substrate including the metal electrode layer, the electron extraction layer, and the photoelectric conversion layer and a positive electrode side substrate including the transparent substrate, the transparent electrode layer, and the hole extraction layer. The PEDOT/PSS can also form an aqueous dispersion, into which an adhesiveness increasing material for increasing adhesion as described below can be mixed.

In the invention, the hole extraction layer, which includes any of the above materials, may optionally contain an adhesiveness increasing material capable of increasing adhesion to the photoelectric conversion layer. This is because when the lamination method is used as described above, adhesion between the photoelectric conversion layer and the hole extraction layer can be increased.

Such an adhesiveness increasing material is not limited as long as it does not inhibit the function of the hole extraction layer, and a sugar chain or the like is preferably used. A sugar chain has good adhesion and a low cost.

Specifically, D-sorbitol or the like can be used as the sugar chain.

While the content of the adhesiveness increasing material is not limited as long as the function of the hole extraction layer is not inhibited, the content of the adhesiveness increasing material in the hole extraction layer-forming material is preferably in the range of 0.1% to 5% by weight, more preferably in the range of 0.5% to 3% by weight, and in particular, preferably in the range of 1% to 2% by weight. When the content is in the above range, higher adhesion can be provided.

In the invention, the thickness of the hole extraction layer is preferably in the range of 10 nm to 200 nm when produced using the organic material or preferably in the range of 0.1 nm to 5 nm when it is the metal thin film.

In the invention, the hole extraction layer may be formed by any method capable of forming it with high precision. Specifically, the hole extraction layer may be formed using a method including applying a hole extraction layer coating liquid containing the above materials, drying the coating, and then baking the coating.

B. Method for Manufacturing Organic Thin-Film Solar Cell

Next, a description is given of the method for manufacturing an organic thin-film solar cell.

The method of the invention for manufacturing an organic thin-film solar cell is a method for manufacturing an organic thin-film solar cell which comprises a metal electrode layer having an aluminum layer on a surface thereof, an electron extraction layer which is a zinc oxide layer formed on the aluminum layer of the metal electrode layer, a photoelectric conversion layer formed on the electron extraction layer, and a transparent electrode layer formed on the photoelectric conversion layer, wherein the manufacturing method comprises a step of: treating the metal electrode layer with zincate to form the electron extraction layer on the aluminum layer of the metal electrode layer.

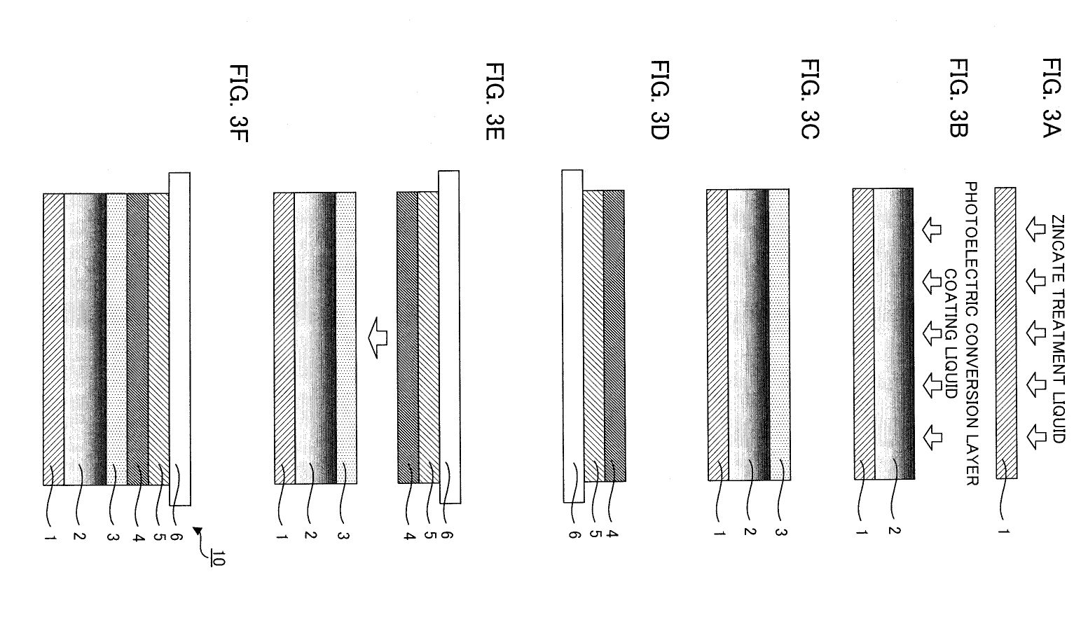

The method of the invention for manufacturing an organic thin-film solar cell is described with reference to the drawings. FIGS. 3A to 3F are schematic process drawings illustrating an example of the method of the invention for manufacturing an organic thin-film solar cell. As illustrated in FIGS. 3A to 3F, an aluminum foil is provided to form the metal electrode layer 1 (FIG. 3A), and the aluminum foil is immersed in a zincate treatment liquid and treated with a zincate, so that the electron extraction layer 2 is formed on the metal electrode layer (FIG. 3B). Subsequently, a photoelectric conversion layer coating liquid is applied onto the electron extraction layer 2 and dried to form a photoelectric conversion layer 3, so that a negative electrode side substrate is formed (FIG. 3C). Subsequently, a transparent substrate 6 with an ITO transparent electrode layer 5 placed thereon is provided, and a hole extraction layer coating liquid is applied onto the transparent electrode layer 5, dried, and baked to form a hole extraction layer 4, so that a positive electrode side substrate is formed (FIG. 3D). Thereafter, as shown in FIG. 3E, the negative electrode side substrate and the positive electrode side substrate are laminated by thermo-compression bonding, so that an organic thin-film solar cell 10 is obtained (FIG. 3F).

FIG. 3A shows the zincate treatment step.

According to the invention, the electron extraction layer is stable under the atmosphere, and therefore, degradation in performance and other problems can be prevented even when any other member is formed on the electron extraction layer under the atmosphere or even when lamination or other processes are performed on the electron extraction layer under the atmosphere.

Thus, a product of stable performance can be easily obtained, for example, by a roll-to-roll process.

The method of the invention for manufacturing an organic thin-film solar cell comprises at least the zincate treatment step.

Hereinafter, a description is given of each step of the method of the invention for manufacturing an organic thin-film solar cell.

The organic thin-film solar cell obtained according to the invention is the same as that described in the section “A. Organic Thin-Film Solar Cell,” and therefore, a repeated description thereof is omitted here.

1. Zincate Treatment Step

In the invention, the zincate treatment step is a step of treating the metal electrode layer with zincate to form the electrode extraction layer on the aluminum layer of the metal electrode layer.

The method for the zincate treatment in this step may be the same as that described in the section “A. Organic Thin-Film Solar Cell,” and therefore, a repeated description thereof is omitted here.

2. Method for Manufacturing Organic Thin-Film Solar Cell

The method of the invention for manufacturing an organic thin-film solar cell, which comprises at least the zincate treatment step, may generally comprises a lamination step of laminating the metal electrode layer and the electron extraction layer, and the photoelectric conversion layer and the transparent electrode layer. If necessary, the method may further comprises any other step generally used in the manufacture of an organic thin-film solar cell, such as hole extraction layer-forming step of forming the hole extraction layer.

In the lamination step according to the invention, the method of laminating the photoelectric conversion layer and the transparent electrode layer may be a method of laminating the photoelectric conversion layer and the transparent electrode layer in this order on the electron extraction layer by a wet process such as a coating process, in which the electron extraction layer is formed by the zincate treatment step, or a method comprises a step of providing a negative electrode side substrate including the metal electrode layer and the electron extraction layer and a positive electrode side substrate with the transparent electrode layer placed thereon and laminating the substrates.

In the lamination, the interface between the negative electrode side substrate and the positive electrode side substrate may be the interface between the photoelectric conversion layer and the transparent electrode layer, between the photoelectric conversion layer and the hole extraction layer, or between the photoelectric conversion layer and the electron extraction layer. Particularly in the invention, the interface is preferably between the photoelectric conversion layer and the hole extraction layer, in other words, the negative electrode side substrate preferably includes the metal electrode layer, the electron extraction layer, and the photoelectric conversion layer, and the positive electrode side substrate preferably includes the transparent substrate, the transparent electrode layer, and the hole extraction layer. In this case, the electron extraction layer and the hole extraction layer are provided so that high photoelectric conversion efficiency can be achieved. Also in this case, good adhesion can be achieved.

The methods of forming the photoelectric conversion layer, the hole extraction layer, the transparent electrode layer, and so on may be the same as those described in the section “A. Organic Thin-Film Solar Cell,” and therefore, a repeated description thereof is omitted here.

The above embodiments are not intended to limit the scope of the invention. The above embodiments are described by way of example only, and it will be understood that many variations are possible with substantially the same feature as recited in the claims to produce the same effect, and all of such variations are within the scope of the invention.

### EXAMPLES

Hereinafter, the invention is more specifically described using an example and a comparative example.

### Example 1

A 5052 material was used as an aluminum foil to form a metal electrode layer. After the surface of the aluminum substrate was cleaned with an alkaline degreasing agent, the aluminum substrate was immersed in a 2% sodium hydroxide solution at 70° C. for 3 minutes so that a passive state film was removed. Subsequently, the aluminum substrate was immersed in an activating agent (50% nitric acid at 25° C.) for 1 minute before a zincate treatment, and then immersed in a zincate bath having the composition shown below for 1 minute. The aluminum substrate was then immersed in the activating agent for 5 seconds so that a zincate film was removed. Subsequently, the aluminum substrate was immersed again in the zincate bath for 30 seconds (double zincate treatment for increasing adhesion).

(Zincate Bath)

SUPER ZINCATE PROCESS SZII™ manufactured by Kizai Corporation

Liquid Composition
Sodium hydroxide 12%
Zinc oxide 2%
Nickel sulfate 0.02%

Temperature 25° C.

After the zincate treatment, the resulting zinc oxide layer has a surface roughness (Ra) of 0.8 μm (0.2 μm before the treatment). The surface roughness was measured with VertScan 2.0™ manufactured by Ryoka System Inc.

After the formation of the zinc oxide layer, a photoelectric conversion layer was formed by a process of applying a composition (P3HT/PCBM) containing P3HT (poly(3-hexylthiophene-2,5-diyl)) layer and PCBM (phenyl C61 butyric acid methyl ester) by die coating under the atmosphere, drying the coating under reduced pressure, and then baking the coating under N₂ at 150° C. for 15 minutes to form a layer having a bulk hetero structure of a mixture of P3HT and PCBM, so that a negative electrode side substrate was obtained.

Subsequently, after a PEN (polyethylene naphthalate) substrate was degreased and cleaned, a metal layer Cr/Cu for an auxiliary electrode was formed on the PEN substrate by sputtering. Thereafter, a mesh metal auxiliary electrode was formed on the PEN substrate using a photo-etching process.

Thereafter, an ITO film was formed as a transparent electrode. Orgacon-S303™ (manufactured by Agfa-Gevaert Group) was applied onto the ITO under the atmosphere by die coating and baked under the atmosphere at 150° C. for 15 minutes, so that a positive electrode side substrate was obtained.

The negative electrode side substrate and the positive electrode side substrate prepared as described above were placed so that the photoelectric conversion layer and the hole extraction layer faced each other, and they were hot-pressed using a roll laminator, so that they were bonded to form a solar cell device.

The bonding was performed under the roll lamination conditions of heating at 150° C. and a load of 4 kgf/cm².

After the preparation, the device was evaluated for performance, and as a result, a conversion efficiency of 2% was obtained under 1 SUN illumination.

Elemental analysis was also performed in the depth direction by X-ray photoelectron spectroscopy (XPS), so that the degree of oxidation of Zn was detected in the depth direction. As a result, it was found that the prepared electron extraction layer had a concentration gradient in which the content of oxygen in the prepared electron extraction layer tended to increase from the metal electrode layer side to the photoelectric conversion layer.

### Reference Signs List

1 metal electrode layer

2 electron extraction layer

3 photoelectric conversion layer

4 hole extraction layer

5 transparent electrode layer

5a auxiliary electrode

5b transparent electrode

6 transparent substrate

10 organic thin-film solar cell

What is claimed is:

1. An organic thin-film solar cell, comprising:
a metal electrode layer having an aluminum layer on a surface thereof;
an electron extraction layer which is a zinc oxide layer formed on the aluminum layer of the metal electrode layer;
a photoelectric conversion layer formed on the electron extraction layer; and
a transparent electrode layer formed on the photoelectric conversion layer,
wherein the electron extraction layer has a concentration gradient in which a content of an oxygen atom in the electron extraction layer tends to increase from the metal electrode layer side to the photoelectric conversion layer.

2. The organic thin-film solar cell according to claim 1, wherein the electron extraction layer contains a zinc layer at a surface of the metal electrode layer side.

3. The organic thin-film solar cell according to claim 1, wherein a surface of the metal electrode layer, on which the electron extraction layer is formed, has an arithmetic mean surface roughness Ra of 5 μm or less.

4. A method for manufacturing an organic thin-film solar cell, in which the organic thin-film solar cell comprises a metal electrode layer having an aluminum layer on a surface thereof, an electron extraction layer which is a zinc oxide layer formed on the aluminum layer of the metal electrode layer, a photoelectric conversion layer formed on the electron extraction layer, and a transparent electrode layer formed on the photoelectric conversion layer, wherein the manufacturing method comprises a step of:
treating the metal electrode layer with zincate to form the electron extraction layer on the aluminum layer of the metal electrode layer.
